(19) United States
(12) Patent Application Publication
(10) Pub. No.: US 2002/0074159 A1
(43) Pub. Date: Jun. 20, 2002

(54) Silicon standoff for fiber optic modules

(76) Inventors: Kendra Gallup, Sunnyvale, CA (US); Brian H. Kim, Fremont, CA (US); Hing Chan, San Jose, CA (US)

Correspondence Address: AGILENT TECHNOLOGIES, Intellectual Property Administration, Legal Department, 51U-PD, P.O. Box 58043, Santa Clara, CA, 95052-8043, US

(21) Appl. No.: 09/738,828

(22) Filed: Dec. 15, 2000

(51) Int. Cl. H05K 1/16

(52) U.S. Cl. 174/260

(57) ABSTRACT

A silicon standoff acts as a shim during reflow between a module and a printed circuit board. The silicon standoff is attached to a flexible circuit. A ball grid array interposes the connection pads of the module and the printed circuit board. The height of the standoff is determined based on the amount of ball collapse that is desired. During reflow, the silicon standoff will not collapse, therefore the ball grid array can only collapse as far as the standoff allows before contacting the printed circuit board.

### FIELD OF THE INVENTION

The invention is directed towards the field of printed circuit boards, particularly towards attaching electrical modules to the printed circuit boards.

### BACKGROUND

When heavy electrical modules, e.g. fiber optic modules, are attached to a printed circuit board using a ball grid array, the balls may collapse. This results in inadequate electrical connection. Rather than improving ball grid array technology, one prior art technique is the gull-wing approach. Wings for connection to board extend beyond the module. These wings are attached to the board using hot-bar soldering. The modules are difficult to align and the increased size uses up large areas of the printed circuit board.

Despite this possible failure, the ball grid array has many advantages over the prior art. First, alignment and attachment to the board is straightforward. The module can be sent through reflow during which the balls in the ball grid array self-align with the pads below and form a bond.

It would be desirable to provide reliable electrical connectivity using the ball grid array technology.

### SUMMARY

The present invention uses a silicon standoff that acts as a shim during reflow. The silicon standoff is attached to a flexible circuit. The height of the standoff is determined based on the amount of ball collapse that is desired. During reflow, the silicon standoff will not collapse, therefore the ball grid array can only collapse as far as the standoff allows before contacting the printed circuit board.

### BRIEF DESCRIPTION OF THE DRAWINGS

FIGS. 1A-B illustrate the present invention.

### DETAILED DESCRIPTION

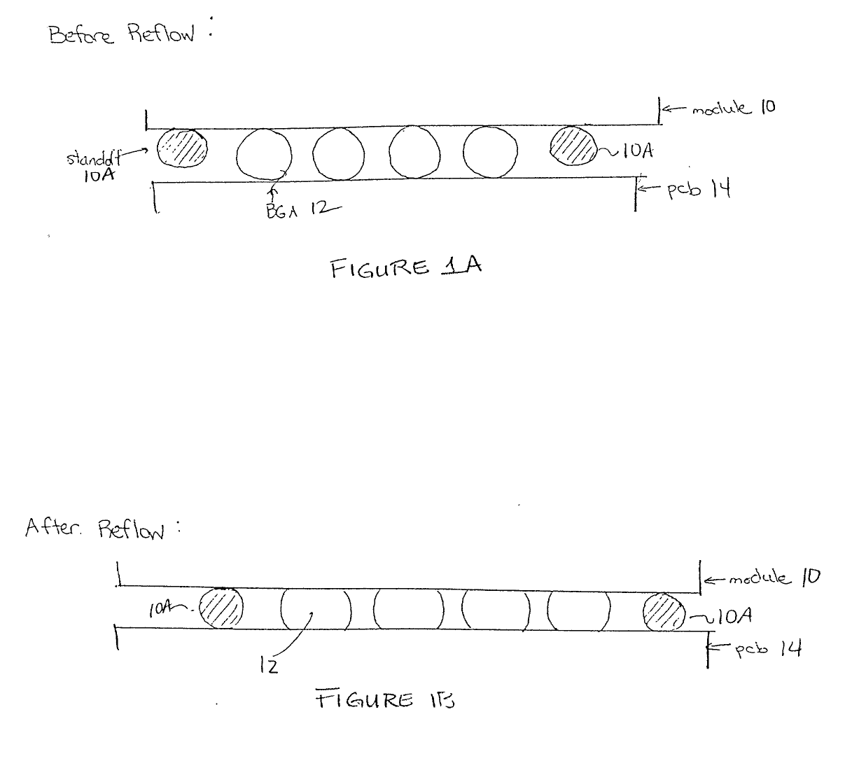

Figures 1A-B illustrate the present invention. FIG. 1A illustrates a module 10 having a silicon standoff 10A prior to reflow. The standoff 10A is attached to a flexible circuit (not shown) that is positioned at the bottom of the module 10. A ball grid array 12 is attached to the flexible circuit. During assembly, the ball grid array 12 is placed against a printed circuit board 14. FIG. 1B illustrates the ball grid array 12 after reflow. The module 10 is positioned at a distance from the printed circuit board 14 such that the ball grid array 12 can provide a sufficient electrical connection.

While the illustrative embodiment uses a silicon standoff, one of ordinary skill in the art would see that any insulative material or dielectric could be used in the place of the silicon. Furthermore, the standoff need not be permanently attached to the module but may be removable after the reflow process has occurred.

We claim:

1. A method for attaching a module to a printed circuit board comprising the steps of:
attaching a standoff to the module;
applying a ball grid array to the module;
positioning the module such that the standoff is between the printed circuit board and the module; and
reflowing the ball grid array.

2. An electrical attachment comprising:
a module having connection pads on a bottom surface;
a standoff, positioned on the bottom surface, having a height;
a printed circuit board having connection pads;
a ball grid array, interposing the connection pads of the module and the printed circuit board, wherein the height of the ball grid array is comparable to the height of the standoff.

3. An electrical attachment, as defined in claim 2, wherein the standoff is an insulative material.

4. An electrical attachment, as defined in claim 3, wherein the insulative material is silicon.

5. An electrical attachment, as defined in claim 2, further comprising a flexible circuit interposing the module and the standoff.

6. An electrical attachment, as defined in claim 5, wherein the standoff is an insulative material.

7. An electrical attachment, as defined in claim 6, wherein the insulative material is silicon.
